(19) United States
(12) Patent Application Publication
(10) Pub. No.: US 2026/0318995 A1
(43) Pub. Date: Oct. 15, 2026

(54) MODIFIED EQUIVALENT CIRCUIT MODELS FOR BATTERY MONITORING

(71) Applicants: GM GLOBAL TECHNOLOGY OPERATIONS LLC, Detroit, MI (US); University of South Carolina, Columbia, SC (US)

(72) Inventors: Taylor Reed Garrick, Bloomfield Hills, MI (US); Brian J. Koch, Berkley, MI (US); Samantha Benson, Royal Oak, MI (US); Erin Efimoff, Oak Park, MI (US); Hunter Teel, Columbia, SC (US)

(73) Assignees: GM GLOBAL TECHNOLOGY OPERATIONS LLC, Detroit, MI (US); University of South Carolina, Columbia, SC (US)

(21) Appl. No.: 19/178,805

(22) Filed: Apr. 14, 2025

(51) Int. Cl. G01R 31/367; B60L 50/60; B60L 53/62; G01R 31/36; G01R 31/3842; G01R 35/00

(52) U.S. Cl. CPC G01R 31/367; B60L 50/60; B60L 53/62; G01R 31/3648; G01R 31/3842; G01R 35/005

(57) ABSTRACT

Systems and methods for monitoring a battery cell experiencing a diffusion-induced State-of-Charge shift are provided. A method includes identifying an equivalent circuit model appropriate for the battery cell; applying a shift function to the equivalent circuit model to define a modified equivalent circuit model; and estimating, using the modified equivalent circuit model, an average surface State-of-Charge for an active material in the battery cell.

### INTRODUCTION

The technical field relates generally to battery monitoring of anodes, cathodes and separators, including using modified equivalent circuit models to monitor surface State-of-Charge.

Lithium ion battery packs may include one or multiple lithium ion battery cells that are electrically connected in parallel or in series, depending upon the needs of the system. Each battery cell includes one or a plurality of lithium ion electrode pairs that are enclosed within a sealed pouch envelope. In some embodiments, each electrode pair includes a negative electrode (e.g., anode) and a positive electrode (e.g., cathode), with a separator arranged therebetween. The separator functions to physically separate and electrically isolate the negative and positive electrodes, while permitting lithium ion transfer.

It would be desirable to provide for battery monitoring of anodes, cathodes, and/or separators. Furthermore, other desirable features and characteristics of the present disclosure will become apparent from the subsequent detailed description and the appended claims, taken in conjunction with the accompanying drawings and the foregoing introduction.

### SUMMARY

In one embodiment, a method for monitoring a battery cell experiencing a diffusion-induced State-of-Charge shift is provided and includes identifying an equivalent circuit model appropriate for the battery cell; applying a shift function to the equivalent circuit model to define a modified equivalent circuit model; and estimating, using the modified equivalent circuit model, an average surface State-of-Charge for an active material in the battery cell.

In certain embodiments of the method, the equivalent circuit model is configured to provide an average State-of-Charge for the active material in the battery cell.

In certain embodiments of the method, estimating the average surface State-of-Charge for the active material includes estimating the average surface State-of-Charge for an anode active material of the battery cell.

In certain embodiments of the method, estimating the average surface State-of-Charge for the active material includes estimating the average surface State-of-Charge for a cathode active material of the battery cell.

In certain embodiments, the method further includes linking a State-of-Lithiation of an anode to a cell State-of-Charge and linking a State-of-Lithiation of a cathode to the cell State-of-Charge using the equations:

x_{A}=[x_{A,charged}−x_{A,discharged}]τ_{cell}+x_{A,discharged}

x_{C}=[x_{C,discharged}−x_{C,charged}][1−τ_{cell}]+x_{C,charged}

where x_{A} is a current State-of-Lithiation of anode active material; x_{A,charged} is the State-of-Lithiation of the anode active material when the cell is at a fully charged state; x_{A,discharged} is the State-of-Lithiation of the anode active material when the cell is at a fully discharged state; x_{C} is a current State-of-Lithiation of cathode active material; x_{C,charged} is the State-of-Lithiation of the cathode active material when the cell is at a fully charged state; x_{C,discharged} is the State-of-Lithiation of the cathode active material when the cell is at a fully discharged state; and τ_{cell} is the State-of-Charge of the cell.

In certain embodiments, the method further includes defining a relationship between an equilibrium potential and the State-of-Lithiation for the anode and for the cathode with a lookup table.

In certain embodiments, the method further includes defining a relationship between an equilibrium potential and the State-of-Lithiation for the anode and for the cathode with a multi-species, multi-reaction model.

In certain embodiments of the method, applying the shift function to the equivalent circuit model to define the modified equivalent circuit model includes modifying a function U=f(SOL), where U is the equilibrium potential, and SOL is the State-of-Lithiation, for the anode and for the cathode, using a State-of-Lithiation shifting term such that: U=f(SOL+SF), where SF is a shift function.

In certain embodiments of the method, the shift function is defined by the equation: SF=AF*I_R/I_ref, where AF is a State-of-Lithiation acceleration factor (AF), I_R is a current passing through the resistor in a resistor capacitor pair; and I_ref is a reference current.

In certain embodiments of the method, I_ref is a maximum charge current.

In certain embodiments, the method, further includes capturing the current passing through the resistor capacitor pair by ordinary differential equation: I_R=v/R+T/R*dv/dt, where T is a diffusion induced State-of-Lithiation acceleration time constant, v is voltage across the resistor capacitor pair, and R is resistance of the resistor.

In certain embodiments, the method further includes setting the resistance of the resistor equal to 1 Ohm.

In certain embodiments, the method further includes simulating various charging events and obtaining output of an average particle State-of-Lithiation and surface particle State-of-Lithiation for the anode and cathode.

In certain embodiments, the method further includes calibrating the time constant (T) and the acceleration factor (AF) based on the output.

In another embodiment, a battery monitoring system is provided and includes at least one battery module including at least one battery cell, the at least one battery cell including at least a cathode, an anode, and a separator between the anode and the cathode; a memory configured to store a cathode equivalent circuit model, an anode equivalent circuit model and a separator equivalent circuit model; and a control module configured to: modify the cathode equivalent circuit model and the anode equivalent circuit model to define a modified cathode equivalent circuit model and a modified anode equivalent circuit model; and determine a surface State-of-Lithiation of the cathode and the anode, based on the modified cathode equivalent circuit model and the modified anode equivalent circuit model. It is noted that the separator is not modified, the V0 in the separator model is 0V vs Li+/Li metal (or whatever the intercalating species is, for example, sodium).

In certain embodiments of the battery monitoring system, the cathode equivalent circuit model is a four parameter (4P) or more equivalent circuit model having one resistor-capacitor pair; the separator equivalent circuit model is a four parameter (4P) or more equivalent circuit model having one resistor-capacitor pair or is set with V0=0 and a single resistor, RO; and the anode equivalent circuit model is a four parameter (4P) or more equivalent circuit model having one resistor-capacitor pair.

In certain embodiments of the battery monitoring system, the control module is configured to determine a virtual reference electrode value by calculating a potential drop between a load of the at least one battery module and a voltage at a connection node between the separator and the anode.

In certain embodiments of the battery monitoring system, the at least one battery module includes multiple battery cells connected in parallel, and a physical reference electrode configured to sense a voltage of at least one of the multiple battery cells.

In another embodiment, a vehicle is provided and includes a drive unit including at least one electric motor configured to rotate wheels of the vehicle; at least one battery module configured to supply power to the at least one electric motor, the at least one battery module including at least one battery cell, the at least one battery cell including at least a cathode, an anode, and a separator between the anode and the cathode; a memory configured to store a cathode equivalent circuit model, an anode equivalent circuit model and a separator equivalent circuit model; and a control module configured to: modify the cathode equivalent circuit model, the anode equivalent circuit model, and the separator equivalent circuit model to define a modified cathode equivalent circuit model, a modified anode equivalent circuit model, and a modified separator equivalent circuit model; and estimate a surface State-of-Lithiation of the cathode and a surface State-of-Lithiation of the anode based on the modified cathode equivalent circuit model and the modified anode equivalent circuit model.

In certain embodiments of the vehicle, the control module is configured to modify charging current based on the surface State-of-Lithiation of the cathode and the surface State-of-Lithiation of the anode.

### DESCRIPTION OF THE DRAWINGS

The present disclosure will hereinafter be described in conjunction with the following drawing figures, wherein like numerals denote like elements, and wherein:

FIG. 1 is a diagram of an example vehicle including a vehicle battery module.

FIG. 2 is a block diagram depicting an anode, separator and cathode of an example battery module.

FIG. 3 is a line diagram depicting example voltage calculations for the battery module of FIG. 2.

FIG. 4 is a flowchart depicting an example process for determining anode, cathode and separator voltages using equivalent circuit models.

FIG. 5 is a flowchart depicting an example process for modifying charging current to avoid a lithium plating condition of a battery module.

FIG. 6 is a flowchart depicting an example process for calculating anode and cathode heat generation for control of vehicle battery cooling.

FIG. 7A is a line graph illustrating an example entropy trend for a graphite material.

FIG. 7B is a line graph illustrating an example entropy trend for a cathode material.

FIG. 8 is a line graph illustrating the calculated overpotential of an anode, cathode, and 3E cell at 50% State-of-Charge in a 3E cell setup.

FIG. 9A is a line graph illustrating the average State-of-Charge vs. the average surface Stage of Charge as a function of time for an anode.

FIG. 9B is a schematic cross section cut view of a portion of an active material particle.

FIG. 10A is a line graph illustrating the offset factor (surface-average) for an anode in a cell/electrochemical model vs. the equivalent circuit model estimate.

FIG. 10B is a line graph illustrating the offset factor (Diffusion Shift Function) as a function of applied current for a charge event, illustrating the time for the concentration gradients in a theoretical particle to fully develop and reach pseudo steady state.

FIG. 11 is a flowchart depicting an example process for monitoring a battery cell experiencing a diffusion-induced State-of-Charge shift.

### DETAILED DESCRIPTION

The following detailed description is merely exemplary in nature and is not intended to limit the application and uses of embodiments herein. Furthermore, there is no intention to be bound by any expressed or implied theory presented in the preceding introduction, summary or the following detailed description. As used herein, the term module refers to any hardware, software, firmware, electronic control unit or component, processing logic, and/or processor device, individually or in any combination, including without limitation: application specific integrated circuit (ASIC), an electronic circuit, a processor (shared, dedicated, or group) and memory that executes one or more software or firmware programs, a combinational logic circuit, and/or other suitable components that provide the described functionality.

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, look-up tables, or the like, which may conduct a variety of functions under the control of one or more microprocessors or other control devices. In addition, those skilled in the art will appreciate that embodiments of the present disclosure may be practiced in conjunction with any number of automated driving systems including cruise control systems, automated driver assistance systems and autonomous driving systems, and that the vehicle system described herein is merely one example embodiment of the present disclosure.

Finally, for the sake of brevity, conventional techniques and components related to vehicle mechanical parts and other functional aspects of the system (and the individual operating components of the system) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment. It should also be understood that the figures are merely illustrative and may not be drawn to scale.

Additionally, the following description refers to elements or features being “connected” or “coupled” together. As used herein, “connected” may refer to one element/feature being directly joined to (or directly communicating with) another element/feature, and not necessarily mechanically. Likewise, “coupled” may refer to one element/feature being directly or indirectly joined to (or directly or indirectly communicating with) another element/feature, and not necessarily mechanically. However, it should be understood that, although two elements may be described below, in one embodiment, as being “connected,” in alternative embodiments similar elements may be “coupled,” and vice versa. Thus, although the schematic diagrams shown herein depict example arrangements of elements, additional intervening elements, devices, features, or components may be present in an actual embodiment.

Electric vehicles include battery modules used to power the vehicle, such as supplying power to one or more electric motors. Example battery modules may include one or more lithium ion battery cells that are electrically connected in parallel or in series, depending upon the needs of the system. Each battery cell includes one or more lithium ion electrode pairs, which may be enclosed within a sealed pouch envelope. In some example embodiments, each electrode pair includes a negative electrode (anode) and a positive electrode (cathode), with a separator arranged therebetween. The separator functions to physically separate and electrically isolate the negative and positive electrodes, while permitting lithium ion transfer.

Each battery module may be configured to electrochemically store and release electric power. In some examples, each anode includes a current collector in the form of a copper foil that is coupled to a negative terminal tab, and each cathode includes current collector with an aluminum foil that is coupled to a positive terminal tab. Lithium-ion battery modules (or other suitable battery module types) are capable of being discharged and re-charged over many cycles.

In some examples, a battery monitoring system uses equivalent circuit models representative of each domain in the battery cell (e.g., an anode, a cathode, and a separator) to calculate the battery cell level potential response, as well as determine the voltage response in the anode, cathode, and separator, for control purposes. Additionally, a virtual reference electrode and/or physical reference electrode may be utilized to calibrate towards an anode lithium plating risk during fast charge scenarios.

A domain specific entropy coefficient (e.g., reversible heat) for the anode and cathode, may be coupled with irreversible heat generation in the cathode, anode, and separator liquid phase, to predict heat generation during operation of the battery module. A control module may derate or extend the drive cycle as necessary based on the determined heat generation for the battery module.

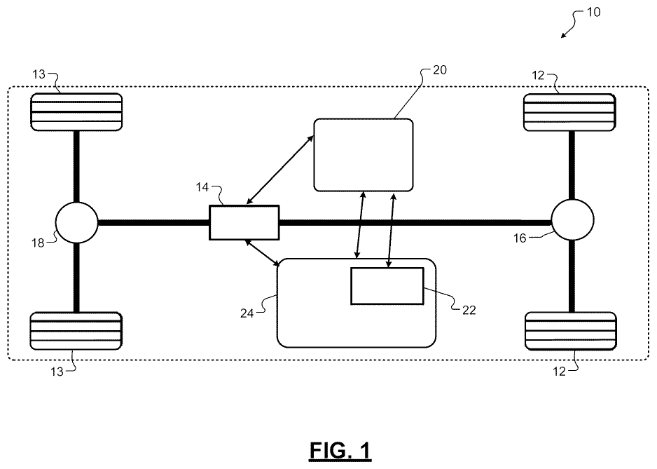

Referring now to FIG. 1, a platform 10 is illustrated. In various implementations, the platform 10 comprises an automobile, such as any one of a number of different types of automobiles, such as, for example, a sedan, a wagon, a truck, sport utility vehicle (SUV), or the like. In certain implementations, the vehicle 10 may also comprise a motorcycle or other vehicle, such as aircraft, spacecraft, watercraft, and so on, and/or one or more other types of mobile platforms (e.g., a robot and/or another mobile platform). In yet other implementations, the platform 10 may be another type of platform, moving or non-moving, such as a building, infrastructure, secondary use, home power, non-automotive, and/or other platform.

As shown in FIG. 1, the illustrated vehicle 10 includes front wheels 12 and rear wheels 13. In FIG. 1, a drive unit 14 selectively outputs torque to the front wheels 12 and/or the rear wheels 13 via drive lines 16, 18, respectively. The vehicle 10 may include different types of drive units. For example, the vehicle may be an electric vehicle such as a battery electric vehicle (BEV), a hybrid vehicle, or a fuel cell vehicle, a vehicle including an internal combustion engine (ICE), or other type of vehicle.

Some examples of the drive unit 14 may include any suitable electric motor, a power inverter, and a motor controller configured to control power switches within the power inverter to adjust the motor speed and torque during propulsion and/or regeneration. A battery system provides power to or receives power from the electric motor of the drive unit 14 via the power inverter during propulsion or regeneration.

While the vehicle 10 includes one drive unit 14 in FIG. 1, the vehicle 10 may have other configurations. For example, two separate drive units may drive the front wheels 12 and the rear wheels 13, one or more individual drive units may drive individual wheels, etc. As can be appreciated, other vehicle configurations and/or drive units can be used.

As shown, the vehicle 10 may further include a control module 20. The control module 20 may be configured to control operation of one or more vehicle components, such as the drive unit 14 (e.g., by commanding torque settings of an electric motor of the drive unit 14). The control module 20 may receive inputs for controlling components of the vehicle, such as signals received from a steering wheel, an acceleration pedal, a brake pedal, etc. The control module 20 may monitor telematics of the vehicle for safety purposes, such as vehicle speed, vehicle location, vehicle braking and acceleration, etc.

The control module 20 may receive signals from any suitable components for monitoring one or more aspects of the vehicle, including one or more vehicle sensors (such as cameras, microphones, pressure sensors, steering wheel position sensors, braking sensors, location sensors such as global positioning system (GPS) antennas, wheel height and/or position sensors, accelerometers, etc.). Some sensors may be configured to monitor current motion of the vehicle, acceleration of the vehicle, braking of the vehicle, current steering direction of the vehicle, current height and/or position of one or more wheels, etc.

The vehicle includes one or more battery modules 24. The battery modules 24 may be configured to supply power to the drive unit 14 to move the vehicle, such as supplying electric power to an electric motor of the vehicle 10. The battery modules 24 may be charged by an external power source, such as an electric utility grid, dedicated electric vehicle chargers, etc.

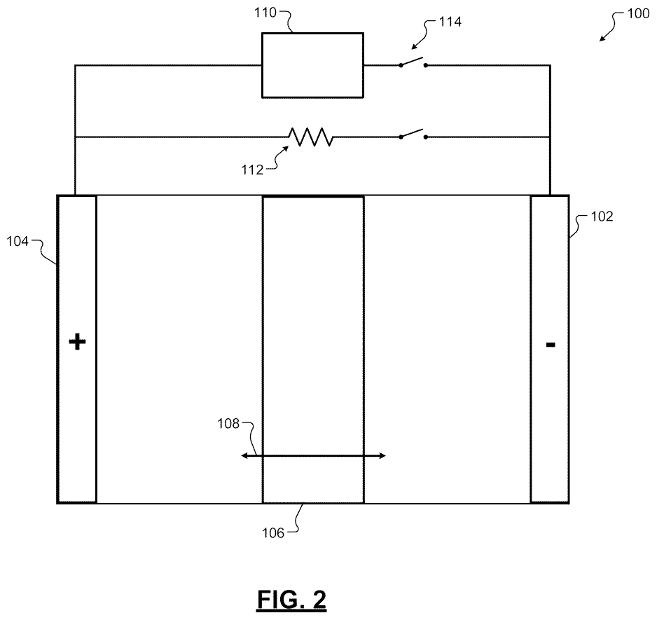

The battery modules 24 may include one or more battery cells, which may each include an anode, a cathode, and a separator, as described further below (e.g., with reference to FIG. 2). The control module 20 may use equivalent circuit models for the anode, the cathode and the separator, to determine voltage responses for the anode, the cathode, the separator, and the cell overall, to execute control operations associated with the battery modules 24.

For example, the control module may be configured to reduce a charging current if an anode voltage reduces below a lithium plating voltage threshold to avoid a lithium plating condition, may reduce a charging current or increase a supply of coolant to avoid a battery overheating condition, etc.

As shown, the vehicle 10 is provided with one or more sensors 22. The sensors 22 may be in communication with the control module 20, where the sensors are configured to sense parameters of the battery modules 24 (such as sensing voltages at different locations within the battery modules 24).

The control module 20 may communicate with another device via a wireless communication interface, which may include one or more wireless antennas for transmitting and/or receiving wireless communication signals. For example, the wireless communication interface may communicate via any suitable wireless communication protocols, including but not limited to vehicle-to-everything (V2X) communication, Wi-Fi communication, wireless area network (WAN) communication, cellular communication, personal area network (PAN) communication, short-range wireless communication (e.g., Bluetooth), etc. The wireless communication interface may communicate with a remote computing device over one or more wireless and/or wired networks. Regarding the vehicle-to-vehicle (V2X) communication, the vehicle 10 may include one or more V2X transceivers (e.g., V2X signal transmission and/or reception antennas).

FIG. 2 is a block diagram depicting an anode 102, separator 106, and cathode 104 of an example battery module 100. For example, the separator 106 may include a permeable membrane placed between the anode 102 and cathode 104 of the battery module 100.

The separator 106 may operate to keep material of the anode 102 and the cathode 104 apart, to inhibit or prevent electrical short circuits, while also allowing the transport of ionic charge carriers that are used to close a circuit during the passage of current in an electrochemical cell. For example, ion transport 108 may occur from the anode 102 to the cathode 104 or vice versa, through the separator 106. This may allow the battery module 100 to either be charged via a charger 110, or to discharge power to a load 112, such as via selective operation of switches 114.

Separators may be used in liquid electrolyte batteries, solid state batteries, polymer electrolyte batteries, etc. The separator 106 may include a polymeric membrane forming a microporous layer. The separator 106 may be chemically and electrochemically stable with regard to the electrolyte and electrode materials, and mechanically strong enough to withstand high tension during battery construction. The separator 106 structure and properties considerably affect the performance of the battery module 100, including the energy and power densities, cycle life, and safety of the battery module 100.

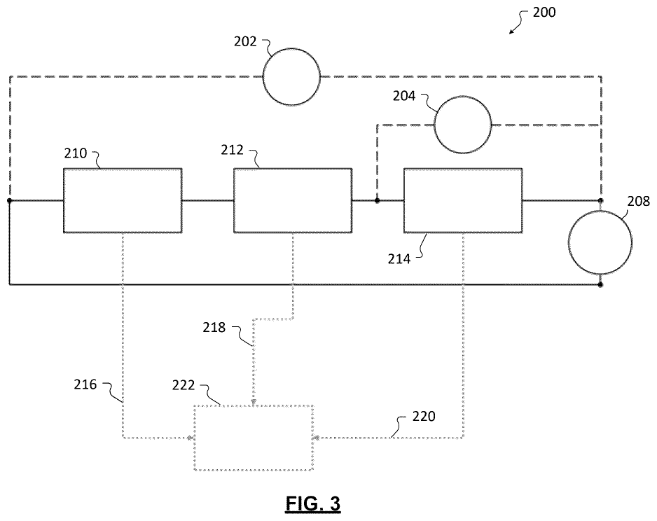

FIG. 3 is a line diagram depicting example voltage calculations for a battery module 200. For example, FIG. 3 illustrates a cell voltage 202, an anode voltage 204, and a load 208 of the battery module 200. Three equivalent circuit models may be used to determine voltage responses for different components of the battery module 200.

For example, a cathode equivalent circuit model 210 may be used to determine a voltage response of the cathode, a separator equivalent circuit model 212 may be used to determine a voltage response of the separator, and an anode equivalent circuit model 214 may be used to determine a voltage response of the anode.

Each equivalent circuit model may have a specified number of parameters. For example, the cathode equivalent circuit model 210, separator equivalent circuit model 212, and/or anode equivalent circuit model 214 may be a four parameter (4P) model, where the four parameters may include a voltage, a resistor and a resistor-capacitor pair, a six parameter (6P) model, where two resistor-capacitor pairs are included, or any suitable number of parameter models may be used, such as an 8P model, a 10P model, etc., which may represent any suitable number of equivalent circuit elements. In certain embodiments, the separator equivalent circuit model may be set with V0=0 and a single resistor, RO.

As shown in FIG. 3, multiple heat generation values may be calculated, which may be specific to different components. For example, the system may calculate a cathode heat generation value 216, a separator heat generation value 218, and an anode heat generation value 220. In some examples, the cathode heat generation value 216 may be calculated according to the following equation:

$${Q}_{Cathode} = I ( {V}_{Cathode} - {OCV}_{Cathode} ) + {TI ( \frac{dU}{dT} )}_{Cathode}$$

In some examples, the anode heat generation value 220 may be calculated according to the following equation:

$${Q}_{Anode} = I ( {V}_{Anode} - {OCV}_{Anode} ) + {TI ( \frac{dU}{dT} )}_{Anode}$$

In some examples, the separator heat generation value 218 may be calculated according to the following equation:

Qₛₑₚₐᵣₐₜₒᵣ=I(ηₛₑₚₐᵣₐₜₒᵣ)

The cathode heat generation value 216, the separator heat generation value 218, and the anode heat generation value 220 may be combined (e.g., summed) to determine a total heat generation value 222 (shown in FIG. 3) for the battery module 200.

In some examples, current for each component may be determined based on a State-of-Lithiation (SOL) associated with a material of the component. The SOL may be implemented in a lookup table, etc. For example, the cathode current may be determined according to the following equation:

$${( \frac{dU}{dT} )}_{Cathode} = f ( SOL )$$

As an example, the cathode current may be determined according to the following equation:

$${( \frac{dU}{dT} )}_{Anode} = f ( SOL )$$

As used above, I may represent current in amps, V_{Cathode} is a measured voltage, and OCV is an equilibrium voltage (e.g., open circuit voltage). dU/dT represents a change in the equilibrium based on a change in temperature (e.g., an entropy coefficient). The entropy of the system may be a function of how much lithium is in the cathode, for example. dU/dT values may be specific to materials used for the cathode and anode respectively, based on amounts of lithiation (such as a Faraday constant times a number of electrons). η_{Separator} may represent an overpotential in the separator, such as how much voltage loss or power loss occurs in the separator when there is a charge.

In some examples, equivalent circuit models may be used to capture voltage responses in a cathode of the battery module, an anode of the battery module, and a separator of the battery module. For example, the cathode voltage response may be captured by a four parameter (4P) equivalent circuit model (e.g., a voltage parameter, a resistance parameter, and a resistor-capacitor pair), the separator liquid phase overpotential may be captured by a 4P equivalent circuit model, and the anode voltage response may be captured by a 6P (e.g., including two resistor-capacitor pairs) or higher equivalent circuit model.

A virtual reference electrode may be utilized by calculating the potential drop between a load of the battery module, and the voltage at the separator/anode connection. In some examples, a battery module may include a grouping of battery cells, such as two or three (or more) cells connected in parallel. The system may assume that the voltage response of each cell connected in parallel will be the same, allowing for virtual prediction of the cell response for the cell grouping. Each cell grouping may have a voltage sensor, a temperature sensor, etc. Some cells may have a physical reference electrode, while others may not.

Heat generation from each domain (e.g., anode, cathode and separator) may be summed to predict the overall heat generation of the battery module during operation, and may be utilized for feedforward calculation and control based on the local and bulk thermal mass. Feedforward calculation may be used, for example, to avoid hitting a thermal limit by quantifying various heat transfer terms in the system, such as a chiller, coolant flow, etc. Feedforward control may be used for a maximum temperature limit. The feedforward control may indicate that a lower power or lower current should be used compared to an instantaneous maximum limit. Integrating the feedforward current prediction may provide an estimate of the total energy transferred to the system.

In some examples, irreversible heat generation in the cathode may be captured by the multiplication of the voltage drop in the cathode and the current (e.g., charging or discharging current of the battery module). Irreversible heat generation in the separator may be captured by the overpotential in the liquid phase multiplied by the current, and irreversible heat generation in the anode may be captured by the multiplication of the voltage drop in the cathode and the current.

Reversible heat generation is considered by the control module, such as by use of entropy coefficients for the cathode and the anode. The entropy coefficient for the cathode may be based on a State-of-Lithiation dependent lookup table (e.g., specific to a material of the cathode), and the reversible heat generation for the cathode may be calculated by the product of the cathode entropy coefficient, a temperature of the battery module, and a current of the battery module. The entropy coefficient for the anode may be based on a State-of-Lithiation dependent lookup table (e.g., specific to a material of the anode), and the reversible heat generation is calculated by the product of the entropy coefficient, temperature, and current. In some examples, feedforward control may consider reversible heat generation to modify a time to reach a thermal limit at any given maximum current, by adding or removing heat to or from the system.

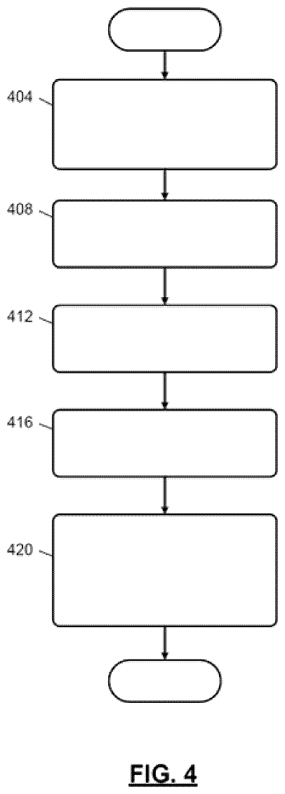

FIG. 4 is a flowchart depicting an example process for determining anode, cathode and separator voltages using equivalent circuit models. The process may be performed by, for example, the control module 20 of FIG. 1. At 404, the process begins by obtaining equivalent circuit models for an anode of a battery module (such as the battery module 24 of FIG. 1), a cathode of the battery module, and a separator of the battery module. For example, the control module 20 may include a memory configured to store equivalent circuit models for each of the anode, the cathode and the separator of the battery module 24.

At 408, the control module determines a cathode voltage response of the cathode using the cathode equivalent circuit model.

At 412, the control module determines an anode voltage response of the anode using the anode equivalent circuit model.

At 416, the control module determines a separator voltage response of the separator using the separator equivalent circuit model.

The process continues at 420 by modifying a charging current supplied to the at least one battery module based on the cathode voltage response, the anode voltage response, and the separator voltage response.

In some examples, the anode voltage response, the cathode voltage response, and the separator voltage response may be combined (e.g., summed) to generate an overall voltage response of the battery module. The voltage responses, individually or in combination, may be used to perform control operations of the battery module, such as estimating a State-of-Charge of the battery module, predicting future (or current) lithium plating or overheating conditions of the battery module, etc.

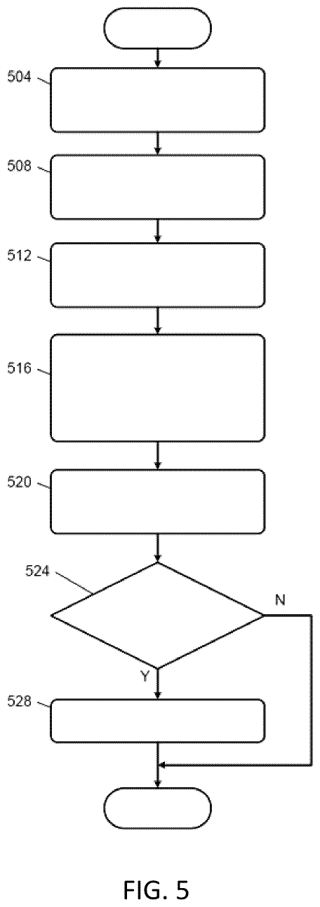

FIG. 5 is a flowchart depicting an example process for modifying charging current to avoid a lithium plating condition of a battery module. The process may be performed by, for example, the control module 20 of FIG. 1. At 504, the process begins by determining a cathode voltage response for a cathode of a battery module (e.g., the battery module 24 of FIG. 1), using an equivalent circuit model.

At 508, the control module determines an anode voltage response of the anode using the anode equivalent circuit model.

At 512, the control module determines a separator voltage response of the separator using the separator equivalent circuit model.

At 516, the control module calculates a virtual reference electrode based on a potential drop between a battery load and a voltage at a connection of the anode and separator.

The control module then compares the anode voltage response to a lithium plating voltage threshold at 520. For example, the control module may determine whether a voltage response of the anode is below a lithium plating voltage threshold indicative of a likelihood or risk of a lithium plating condition occurring at the battery module (e.g., on the anode of the battery module).

When the anode voltage is less than the lithium plating voltage threshold at 524, the control module decreases a charging current supplied to the battery module. Reducing the charging current may inhibit or prevent the lithium plating condition from occurring, because the anode voltage may rise in response to a reduction in charging current. In some examples, a limit may be set at 0V versus Li+/Li metal, a positive offset (e.g., 10 mV versus Li+/Li metal), etc., which may depend on how conservative or aggressive a charge control is desired to be.

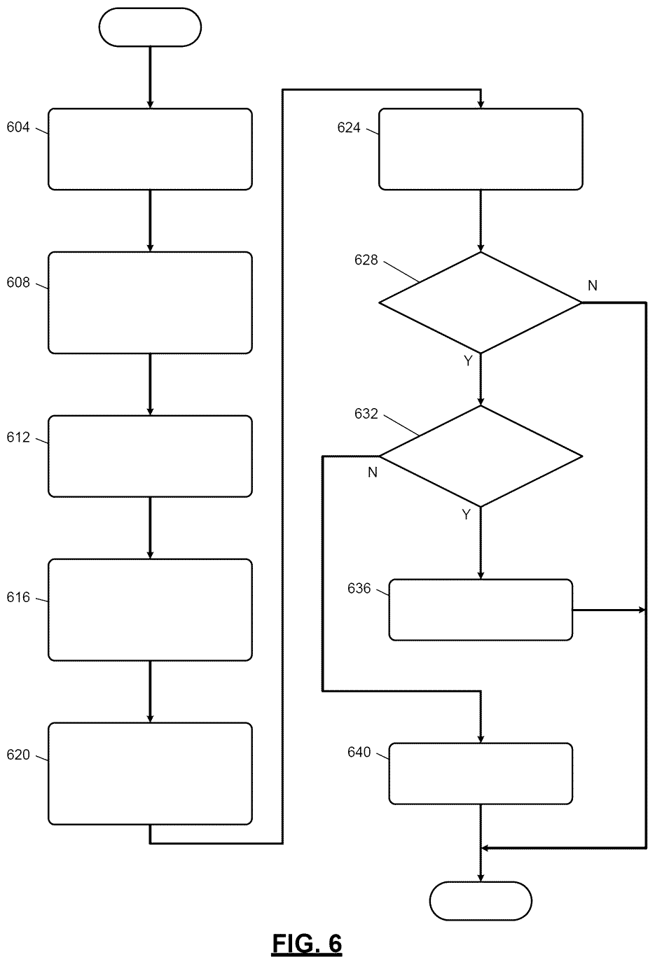

FIG. 6 is a flowchart depicting an example process for calculating anode and cathode heat generation for control of vehicle battery cooling. The process may be performed by, for example, the control module 20 of FIG. 1. At 604, the process begins by calculating an anode irreversible heat generation in the battery module, such as by multiplying an anode voltage drop with a current (e.g., a current though the anode).

At 608, the control module calculates a separator irreversible heat generation value, which may be based on multiplying a liquid phase overpotential of the separator with a current (e.g., a current through the separator, a current of the battery module, etc.).

The process continues at 612 where the control module calculates a cathode irreversible heat generation based on, for example, multiplying a cathode voltage drop with a current (e.g., a current through the cathode).

At 616, the control module calculates an anode reversible heat generation using an anode entropy coefficient. The anode entropy coefficient may be determined by a State-of-Lithiation (SOL) look up table, which may correspond to a material of the anode (such as graphite, etc.).

The control module calculates a cathode reversible heat generation at 620, using a cathode entropy coefficient. The cathode entropy coefficient may be determined by a State-of-Lithiation (SOL) look up table, which may correspond to a material of the cathode (such as an NMC-811 cathode material, etc.).

At 624, the control module compares a total heat generation value (which may be based on a combination of separately calculated heat generation values for the anode, cathode and separator), to a heat threshold indicative of an overheating condition. For example, a heat threshold may be set (such as via experimentation, modeling, etc.), which is indicative of a risk or likelihood of an overheating condition of the battery module (e.g., a thermal runaway condition of the battery module).

When the total heat generation value is greater than the heat threshold at 628, the control module proceeds to 632 to determine a current setting for cooling the battery or avoiding an overheating condition. For example, the control module may determine at 632 whether a heat reduction approach is set to increasing a flow of coolant. If so, the control module proceeds to 636 to increase a coolant supplied to the battery module to cool the battery module and avoid the overheating condition. Additionally, or alternatively, the control module may reduce a charging current supplied to the battery module at 640 (or reduce a current flowing out of the battery module), to cool the battery and avoid an overheating condition.

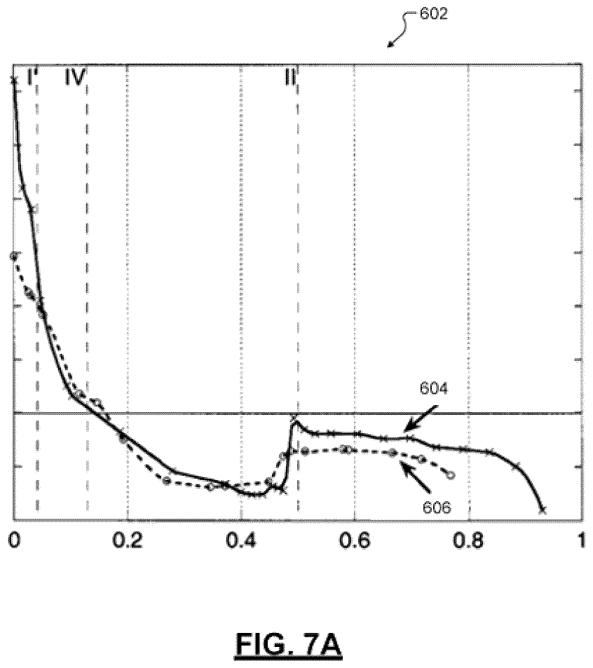

FIG. 7A is a line graph illustrating an example entropy trend 602 for a graphite material, where the horizontal axis is x of LiₓC₆. FIG. 7A illustrates a natural graphite entropy coefficient 604 with respect to a State-of-Lithiation. The natural graphite material may be used for an anode, for example. FIG. 7A also illustrates an MCMB entropy coefficient 606 for mesocarbon microbeads at 2800 degrees Celsius.

FIG. 7B is a line graph illustrating an example entropy trend 608 for a cathode material. The boxes represent measured values and the lines interconnecting the boxes represent interpolated values. In FIG. 7B, the y-axis represents the entropic coefficient of NMC-811/mV^{k-1}. FIG. 7B illustrates a cathode material entropy coefficient 610 with respect to a State-of-Lithiation. The cathode material may be any suitable material for use as a cathode, such as an NMC-811 cathode material.

Some example embodiments described herein may utilize an equivalent circuit model to capture the cathode, anode, and separator voltage response, such as in a vehicle battery module. However, the example embodiments are not limited to vehicles, and may be used to analyze other battery types having anodes, cathodes and separators, in implementations other than vehicles.

In some examples, the cathode voltage response may be captured by a 4P (or higher order) equivalent circuit model, the separator liquid phase overpotential may be captured by a 4P (or higher order) equivalent circuit model, and the anode voltage response may be captured by a 4P (or higher order) equivalent circuit model. A virtual reference electrode may be utilized by calculating the potential drop between the battery load and the voltage at the separator/anode connection of the battery.

A control module may be configured to calculate the heat generation from each domain (e.g., anode, cathode and separator), and sum the individual heat generation values to predict total heat generation during operation of the battery module. This may be utilized for feedforward calculation and control of the battery module, based on the local and bulk thermal mass.

Some example embodiments may calculate irreversible heat generation from the equivalent circuit model in each domain (e.g., anode, cathode and separator). For example, irreversible heat generation in the cathode may be captured by the multiplication of the voltage drop in the cathode and the current, irreversible heat generation in the separator may be captured by the overpotential in the liquid phase multiplied by the current, and irreversible heat generation in the anode may be captured by the multiplication of the voltage drop in the anode and the current.

Some example embodiments may calculate reversible heat generation in the anode and cathode, using an anode entropy coefficient and a cathode entropy coefficient. For example, the entropy coefficient for the cathode may be based on a State-of-Lithiation dependent lookup table, and the reversible heat generation for the cathode may be calculated by the product of the cathode entropy coefficient, temperature, and current. The entropy coefficient for the anode may be based on a State-of-Lithiation dependent lookup table, and the reversible heat generation for the anode may be calculated by the product of the entropy coefficient, temperature, and current. In some examples, a Kalman filter may be used to aid state estimation for State-of-Lithiation calculations, for internal variable tracking.

Various example embodiments may provide one or more advantages for battery module monitoring, such as explicit calculation of the battery cell potential, explicit calculation of the cathode potential, explicit calculation of the anode potential, and explicit calculation of the separator overpotential in the liquid phase. These values may be used for control operations of the battery module based on the cathode, anode, and cell potential.

Irreversible heat generation calculation in each domain may be used for a feed forward determination of the heat generation. Reversible heat generation calculation in the anode and cathode may be used, such as for low current use cases (e.g., limited charging due to a cooling failure, limited charging due to a coolant pump failure, or propulsion derating due to thermal limits, etc.).

In some examples, the anode potential may be used for determination of a lithium plating risk, such as during a fast ECM strategy in a vehicle. Overall cell response may be updated as the battery module ages, based on individual changes in voltage responses of the anode, cathode and separator, for example.

Equivalent circuit models (ECM) may utilize coulomb counting and a lookup table for the open circuit voltage of the electrode active material (AM) in order to link the State-of-Charge of the cell, State-of-Lithiation of the AM, and equilibrium potential. However, the electrochemical reaction at the surface of AM particles in porous electrodes containing a solid matrix and electrolyte phase considers the potential at the surface of the AM particles, which is a function of the applied rate (Applied charge rate, i.e., applied current), characteristic diffusion coefficient, and characteristic diffusion length (radius). The equilibrium potential at the surface of the AM particles, linked to the State-of-Lithiation (SOL) at the surface of the AM particles, is not equal to the average SOL of the AM particles (except at equilibrium, such as after a long rest time). Rather, the equilibrium potential is shifted based on the shift between the average particle SOL, and the surface SOL of the AM particle. Embodiments herein details the shift of the SOL in an ECM half-cell to match reality.

In certain embodiments, an equivalent circuit model may be provided having resistance and capacitor pairs in series to capture time constants. When a time constant is quantified for each domain in the anode, the separator, and the cathode, they can be characterized individually, and then an equivalent circuit model can be used in a platform such as a vehicle, a lab, or a simulation environment to capture the losses in the anode, separator, and cathode sub domains of the battery cell.

Certain embodiments herein use a State-of-Lithiation shift function that is sensitive to the overall charge or discharge rate of the cell. This State-of-Lithiation shift function may contain the following aspects:

1. State-of-Lithiation is shifted higher in the anode during charge and shifted lower in the anode during discharge. State-of-Lithiation is shifted higher in the cathode during discharge and shifted lower in the cathode during charge. (This is in contrast to the absence of a shift function in standard equivalent circuit modeling).
2. The State-of-Lithiation shift function is captured using a characteristic time constant, which is captured by a single (or in some embodiments, multiple) resistor-capacitor pair(s). (This is in contrast to the absence of a time constant in standard equivalent circuit modeling).
3. A continuous resistance constraint is considered during the simulation of a fast-charging event such that the State-of-Charge shift time constant and the continuous resistance constraint time constant are of the same order of magnitude. (This is in contrast to the absence of a constraint in current equivalent circuit modeling).
4. The State-of-Lithiation shift function time constant is rate dependent is certain embodiments and is temperature dependent, as diffusion is a function of temperature as well.
5. The State-of-Lithiation shift function may capture the impact of electrolyte concentration gradient development time constants in certain embodiments.

In certain embodiments herein, the diffusion induced State-of-Charge shift simplifies the model (reduces the break points for low State-of-Charge resistance lookups).

Certain embodiments herein use a physics based estimation of heating during operation.

Certain embodiments herein provide a pathway for parameter sets to capture pulse and continuous rate performance.

Certain embodiments herein include explicit calculation of the cell, cathode, anode, and separator overpotential.

Certain embodiments herein mitigate the need to have State-of-Charge dependent resistance variation to capture the State-of-Charge shifting.

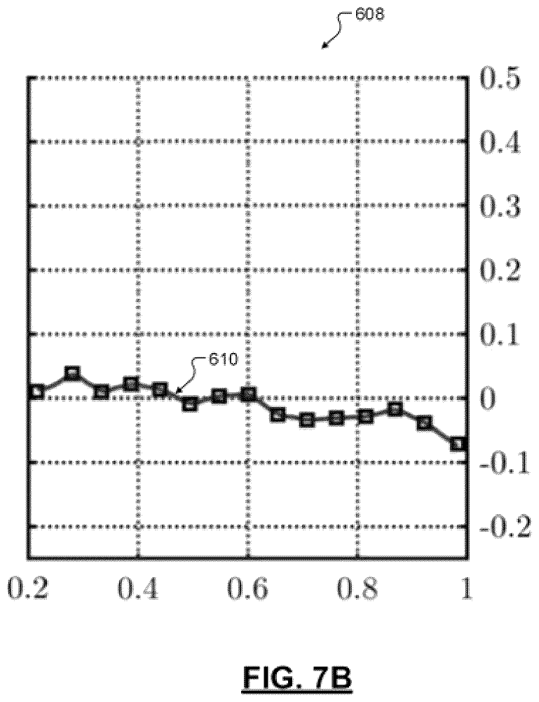

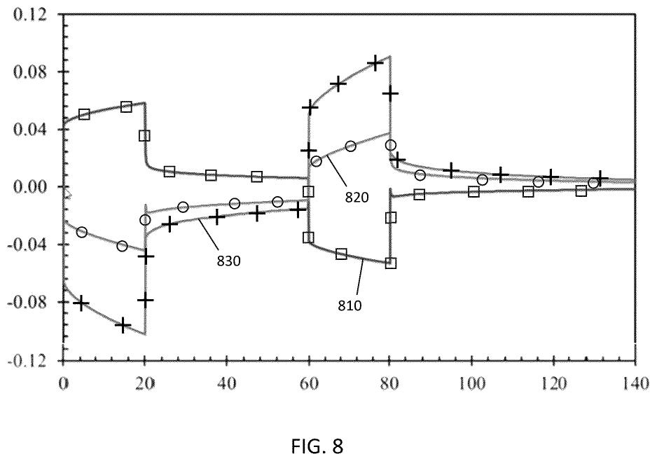

FIG. 8 illustrates the calculated overpotential of an anode, cathode, and 3E cell at 50% State-of-Charge in a 3E cell setup. Line 810 represents the anode overpotential, line 820 represents the cathode overpotential, and line 830 represents the 3E cell overpotential. The x-axis represents time in seconds. The Y-axis represents overpotential in V.

As shown, operation of a battery cell may start from a rest state. When a pulse or any other load case is applied to the battery cell, there is a deviation from the starting equilibrium potential, where there is no overpotential, to some perturbation from that equilibrium, which is the work done by the system or the work the system does on the surroundings.

Embodiments below provide for deconvoluting the differences between the losses of the resistances in the anode domain (liquid or solid), the cathode domain (liquid or solid), and the separator domain (liquid).

Certain embodiments herein provide a modified equivalent circuit model for diffusion induced State-of-Charge shift.

For example, a long time constant operation, for example a DC fast charge operation, may induce a concentration gradient throughout the radial direction of a theoretical active material particle in a battery cell.

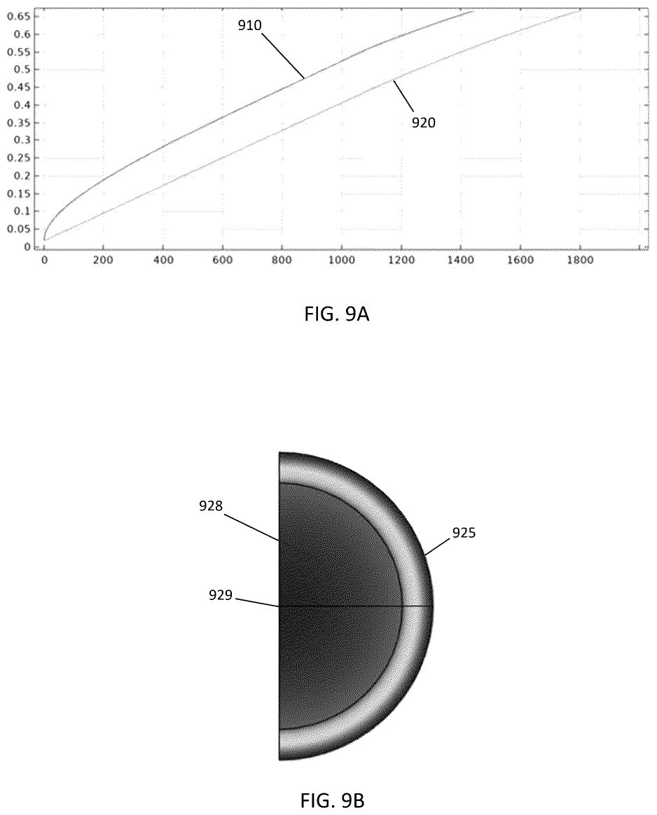

FIG. 9A is a graph of the average State-of-Charge vs. the average surface Stage of Charge as a function of time for an anode. In FIG. 9A, the average surface State-of-Charge is indicated by line 910 and the average surface State-of-Charge is indicated by line 920. In FIG. 9A, the x-axis represents time in seconds and the y-axis represents State-of-Charge.

FIG. 9A illustrates the gap that develops in the State-of-Lithiation (State-of-Charge) when considering the diffusion of lithium in a solid particle. At low rates, a minimal gap exists, and the higher the rate, the larger the gap. The State-of-Lithiation at the surface of the particle feeds the calculation of the equilibrium potential, which is used to calculate terminal voltage, determine proximity to lithium plating onset, and provides one of the terms in the kinetic rate expression typically seen in physics-based battery modeling.

FIG. 9B is a partial cross section cut view illustrating lithium concentration distribution in a portion of an active material particle 928, such as an active anode material particle. In FIG. 9B, bands of lithium concentrations are illustrated in different shades. During a charging operation of a battery cell, higher lithium concentrations are located at the outer surface 925 of the active anode material particle 928 where the reaction occurs, with concentrations diffusing toward the center 929 of the particle 928. During delithiation, lower concentrations are located at the outer surface 925 of the active anode material particle 928 where the reaction occurs, with concentrations increasing toward the center 929 of the particle 928.

Referring to the equivalent circuit model of FIG. 3, the equilibrium potential (V₀) is traditionally provided from a look up table, which may be loaded on the control module, such that a given charge on a given capacity can be linearly interpolated to provide a percent change in the State-of-Charge.

As described herein, such a linear interpolation cannot be used in the case of long time constant operation due to the non-linear response of the average surface State-of-Charge (line 920) indicated in FIG. 9A. The State-of-Charge at the surface is paramount because electrochemical reaction kinetics are determined by the interface, i.e., the concentration at the particle surface.

Therefore, in an equivalent circuit model that uses coulomb counting to determine State-of-Charge for the average anode material and then obtains from a lookup table the average voltage for the equilibrium potential, the obtained voltage may be off by up to ten percent from the kinetics at the particle surface.

Embodiments herein recognize this deviation between the potential at the particle surface and the potential calculated from a coulomb counted linear response. Further, embodiments herein obtain the potential at the particle surface. Electrochemical calculations may use the potential at the particle surface to evaluate the performance of the battery cell.

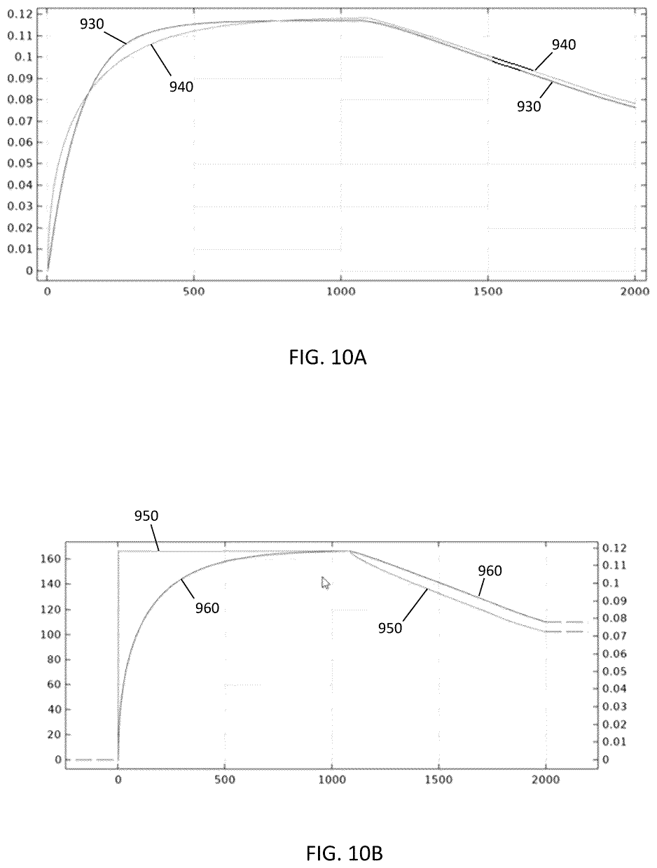

FIG. 10A illustrates the offset factor (surface-average) for an anode in a cell/electrochemical model vs. the equivalent circuit model estimate. FIG. 10B illustrates the offset factor (Diffusion Shift Function) as a function of applied current for a charge event, illustrating the time for the concentration gradients in a theoretical particle to fully develop and reach pseudo steady state.

In FIG. 10A, line 930 represents the offset factor (surface-average) for a material either measured or captured with a full set of governing partial differential equations, line 940 illustrates that the offset factor may be captured with a time constant, which may be analogous to a single resistor-capacitor pair or two resistor-capacitor pairs. In FIG. 10a, the x-axis represents time in seconds and the y-axis represents the offset factor.

The anode local State-of-Lithiation is linked to the cell State-of-Charge via the equation:

x_{A}=[x_{A,charged}−x_{A,discharged}]τ_{cell}+x_{A,discharged}
where
x_{A} is the current State-of-Lithiation of the anode active material;
x_{A,charged} is the State-of-Lithiation of the anode active material when the cell is at the fully charged state;
x_{A,discharged} is the State-of-Lithiation of the anode active material when the cell is at the fully discharged state; and

The cathode local State-of-Lithiation is linked to the cell State-of-Charge via the equation:

x_{C}=[x_{C,discharged}−x_{C,charged}][1−τ_{cell}]+x_{C,charged}
where
x_{c} is the current State-of-Lithiation of the cathode active material;
x_{C,charged} is the State-of-Lithiation of the cathode active material when the cell is at the fully charged state; and
x_{C,discharged} is the State-of-Lithiation of the cathode active material when the cell is at the fully discharged state; and
τ_{cell} is the State-of-Charge of the cell.

These fully charged and fully discharged states are typically defined based on a cell potential at rest. For example, 4.2V cell potential when τ_{cell}=1, and 2.5V cell potential when τ_{cell}=0, for nickel based cathodes; LFP, LTO, etc would have different setpoints.

It is noted that the State-of-Lithiation (x_{A} or x_{C}) refers to the degree to which lithium ions are inserted into the active material of the particle (e.g., graphite in the anode or a metal oxide in the cathode). It is typically expressed as a fractional value. When x=0, the material is fully delithiated (no lithium is inserted), and when x=1, the material is fully lithiated (saturated with lithium).

Thus, the average State-of-Lithiation is a measure of the bulk lithium concentration within the particle, averaged over its volume, while the surface State-of-Lithiation is a measure of the bulk lithium concentration within the surfaced volume of particle, averaged over its surface volume.

The surface State-of-Charge refers to the local State-of-Charge at the particle's surface, which is determined by the lithium concentration near the surface of the particle, i.e., the average surface State-of-Lithiation. It is influenced by the rate of lithium-ion transport into or out of the particle and differs from the bulk SOL due to concentration gradients, especially during fast charging or discharging. The surface SOC is tied to the electrochemical reactions occurring at the particle-electrolyte interface.

In FIG. 10B, the x-axis represents charge time in seconds and, the lefthand y-axis represents the current in A, and the righthand y-axis represents the diffusion shift function. Further, line 950 represents the applied current and line 960 represents the diffusion shift function, indicative of the non-linear response having an associated time constant. At about 1100 seconds, the applied current is reduced and the shift function goes down.

In the illustrated example of FIGS. 10A and 10B, the battery cell is rated for a 166 amp current, and the shift function is defined from that basis function and an offset factor is calibrated. In the illustrated example, the offset factor would be a 12% State-of-Charge shift. When 166 amp, i.e., maximum current, is applied, with the shift function approaches but does not theoretically reach the 0.115 offset, as shown in FIG. 10A. As the applied current decreases, the offset factor also decreases.

The shift function (SF) is a function of a State-of-Lithiation acceleration factor (AF), and the ratio between the current passing through the resistor in a resistor capacitor pair (I_R) and a reference current (I_ref) (typically defined as the maximum charge current). In other words, SF=AF*I_R/I_ref. The reference current (I_ref) may be calibrated from test data. The acceleration factor (AF) is a function of temperature as it is constant at a given temperature.

The current passing through the resistor capacitor pair is captured by the ordinary differential equation: I_R=v/R+T/R*dv/dt, where T is the diffusion induced State-of-Lithiation acceleration time constant, v is the voltage across the RC couple, and R is the resistance of the resistor. The time constant T may be temperature dependent and may be State-of-Lithiation dependent.

The equilibrium potential (or open-circuit potential, OCP) of an active material is the voltage of the electrode material at rest (no current flowing) and is a function of the lithium concentration within the material. For a given active material (e.g., graphite, LiCoO₂), the OCP is typically a function of the SOL or SOC, determined experimentally or through thermodynamic models.

When looking up the equilibrium potential at a given time step, the function U=f(SOL), where U is the equilibrium potential, and SOL is the State-of-Lithiation of the electrode, can be modified using a State-of-Lithiation shifting term such that: U=f(SOL+SF), where SF is the shift function.

Thus, during use of a battery cell, the anode response and the cathode response may be measured separately by locating a reference electrode between the anode and cathode. For example, the anode response and cathode response may be monitored while charging the battery cell at different rates from a low State-of-Charge. The Shift Factor (SF), Acceleration Factor (AF), and time constant T may then be calculated from the monitored data. For example, the calculations may use a Newman-type model based on a partial differential equation (PDE) for a selected model.

It is noted that there is no state of charge shift for the separator; it's a concentration gradient and resistive loss function that is considered in some embodiments. For example, the separator could have a 2 mV to 20 mV potential drop (e.g., for lithium ion; polymer or solid state would be higher), and this is a function of the applied rate, tortuosity, and electrolyte. This loss can be equally applied to the anode and cathode signals serving to offset the potential estimated in the anode or cathode from the measured value at the reference electrode that is placed in the middle of the separator. If this is not done, then there could be some error when calibrating and using the offset function for the anode and cathode; for some cells, this is ignored.

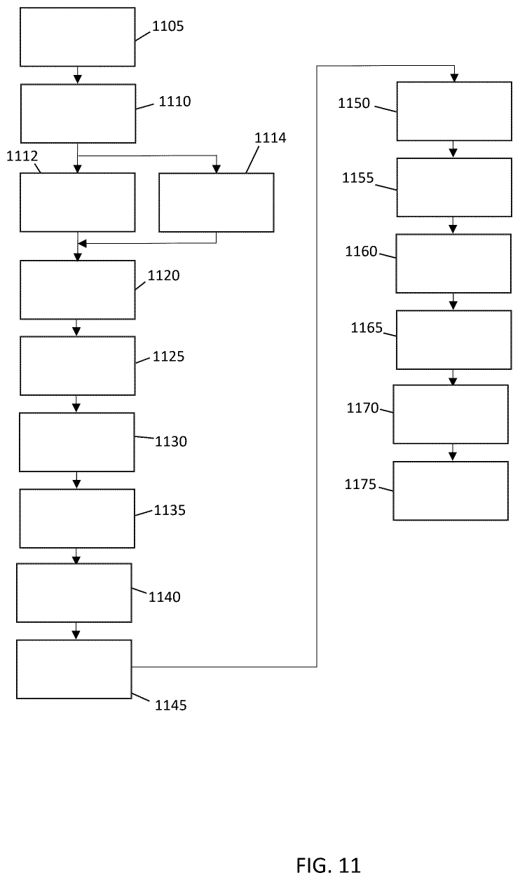

FIG. 11 is a flowchart depicting an example process for modifying an equivalent circuit model for diffusion induced State-of-Charge shift.

At 1105, the process includes loading a specific equivalent circuit model to the control module, such as the control module 20 of FIG. 1. In the domain specific equivalent circuit model, the cathode voltage response can be captured by an equivalent circuit model with at least one equilibrium potential voltage source, one resistor in series representing the ohmic resistance of the cathode, and at least one resistor-capacitor (RC) pair in series to capture the diffusive response of the cathode; the anode voltage response can be captured by an equivalent circuit model with at least one equilibrium potential voltage source, one resistor in series representing the ohmic resistance of the cathode, and at least two resistor-capacitor (RC) pairs in series to capture the diffusive response of the cathode; the separator overpotential can be captured by at least one resistor-capacitor pair; the difference between the separator overpotential and the anode potential represents a virtual reference electrode; and the equilibrium potential of the anode and cathode are modified according to an entropy coefficient that captures the temperature dependence of the equilibrium potential.

The following operations may be performed by, for example, the control module 20 of FIG. 1.

At 1110, the process includes linking the State-of-Lithiation of the anode and cathode to the cell State-of-Charge. For example, the State-of-Charge of the cell may be linked to the State-of-Charge of the anode and cathode using the cell balancing parameters in the following equations:

x_{A}=[x_{A,charged}−x_{A,discharged}]τ_{cell}+x_{A,discharged}

x_{C}=[x_{C,discharged}−x_{C,charged}][1−τ_{cell}]+x_{C,charged}

At 1112, the process may include defining the relationship between the equilibrium potential and the State-of-Lithiation with a lookup table.

Alternatively to 1112, the process may include, at 1114, defining the relationship between the equilibrium potential and the State-of-Lithiation with the multi-species, multi-reaction model.

The process may include, at 1120, modifying, the relationship between the equilibrium potential and State-of-Lithiation.

When looking up the equilibrium potential at a given time step, the function U=f(SOL), where U is the equilibrium potential, and SOL is the State-of-Lithiation of the electrode, can be modified using a State-of-Lithiation shifting term such that: U=f(SOL+SF), where SF is the shift function.

At 1125, the process defines the shift function SF as SF=AF*I_R/I_ref. Thus, the shift function (SF) is a function of a State-of-Lithiation acceleration factor (AF), and the ratio between the current passing through the resistor in a resistor capacitor pair (I_R) and a reference current (I_ref) (typically defined as the maximum charge current).

At 1130, the process captures the current passing through the resistor capacitor pair by the ordinary differential equation: I_R=v/R+T/R*dv/dt, where T is the diffusion induced State-of-Lithiation acceleration time constant, v is the voltage across the RC couple, and R is the resistance of the resistor.

At 1135, the process arbitrarily sets R equal to 1 Ohm. Specifically, because the resistor is only used to determine the shift function response tied to the time constant at 1130, the resistor can be arbitrarily set to 1 Ohm.

At this point in the process, the modified equivalent circuit model is set up. After the modified equivalent circuit model is set up, the process may take the standard Newman Pseudo 2 Dimensional model that has been calibrated to cell performance data with a reference electrode and simulate various charging events according to the typical vehicle load cases, with a unique output of the average anode particle State-of-Lithiation and the surface particle State-of-Lithiation. This is then used as the objective target function to calibrate the time constant (T) and the acceleration factor (AF).

After calibrating the shift function, the remaining equivalent circuit parameters are calibrated to cell terminal voltage signals, or to anode and cathode terminal potential vs. reference signals. It is noted that the overpotential parameters for the separator can be directly input without parameter estimation using the tortuosity of the separator and the associated salt flux, based on the required transport from one electrode to another during the maximum current load case as detailed above (166A)

For example, at 1140, the process loads the porous electrode model for the electrochemical cell (battery) in scope.

At 1145, the process calibrates the porous electrode model, such as by using a standard 3 Electrode fast charging protocol.

At 1150, the process uses the porous electrode model to parametrically output the average and surface State-of-Lithiation for the anode.

At 1155, the process may restrict to a desired range such as 0.1C to 3C and from 0 to 0.2 cell SOC as a starting condition. These are typical DC Fast Charging start point conditions, but the process can be used at any temperature, state of charge, and starting charge rate.

At 1160, the process calibrates the shift factor time constant (T) and the acceleration factor (AF) using the outputs from the electrochemical model and any standard parameter estimation package.

At 1165, the process calibrates the equivalent circuit parameters using the explicit signal for each domain (anode, cathode) from the 3 Electrode charging protocol.

At 1170, the process calibrates the separator equivalent model parameters using the voltage drop in the tortuous liquid phase considering the conductivity of the electrolyte.

At 1175, the process virtually sweeps through thousands of desired fast charging scenarios for virtual validation at early design vehicle phase to provide proximity to lithium plating.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

While at least one exemplary embodiment has been presented in the foregoing summary and detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing summary and detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A method for monitoring a battery cell experiencing a diffusion-induced State-of-Charge shift, the method comprising:
identifying an equivalent circuit model appropriate for the battery cell;
applying a shift function to the equivalent circuit model to define a modified equivalent circuit model; and
estimating, using the modified equivalent circuit model, an average surface State-of-Charge for an active material in the battery cell.

2. The method of claim 1, wherein the equivalent circuit model is configured to provide an average State-of-Charge for the active material in the battery cell.

3. The method of claim 1, wherein estimating the average surface State-of-Charge for the active material comprises estimating the average surface State-of-Charge for an anode active material of the battery cell.

4. The method of claim 1, wherein estimating the average surface State-of-Charge for the active material comprises estimating the average surface State-of-Charge for a cathode active material of the battery cell.

5. The method of claim 1, further comprising linking a State-of-Lithiation of an anode to a cell State-of-Charge and linking a State-of-Lithiation of a cathode to the cell State-of-Charge using the equations:
x_{A}=[x_{A,charged}−x_{A,discharged}]τ_{cell}+x_{A,discharged}
x_{C}=[x_{C,discharged}−x_{C,charged}][1−τ_{cell}]+x_{C,charged}
where
x_{A} is a current State-of-Lithiation of anode active material;
x_{A,charged} is the State-of-Lithiation of the anode active material when the cell is at a fully charged state;
x_{A,discharged} is the State-of-Lithiation of the anode active material when the cell is at a fully discharged state;
x_{C} is a current State-of-Lithiation of cathode active material;
x_{C,charged} is the State-of-Lithiation of the cathode active material when the cell is at a fully charged state;
x_{C,discharged} is the State-of-Lithiation of the cathode active material when the cell is at a fully discharged state; and
τ_{cell} is the State-of-Charge of the cell.

6. The method of claim 5 further comprising defining a relationship between an equilibrium potential and the State-of-Lithiation for the anode and for the cathode with a lookup table.

7. The method of claim 5 further comprising defining a relationship between an equilibrium potential and the State-of-Lithiation for the anode and for the cathode with a multi-species, multi-reaction model.

8. The method of claim 5, wherein applying the shift function to the equivalent circuit model to define the modified equivalent circuit model comprises
modifying a function U=f(SOL), where U is the equilibrium potential, and SOL is the State-of-Lithiation, for the anode and for the cathode, using a State-of-Lithiation shifting term such that: U=f(SOL+SF), where SF is a shift function.

9. The method of claim 8, wherein the shift function is defined by the equation:
SF=AF*I_R/I_ref
where: AF is a State-of-Lithiation acceleration factor (AF),
I_R is a current passing through the resistor in a resistor capacitor pair; and
I_ref is a reference current.

10. The method of claim 9, wherein I_ref is a maximum charge current.

11. The method of claim 9, further comprising:
capturing the current passing through the resistor capacitor pair by ordinary differential equation: I_R=v/R+T/R*dv/dt
where: T is a diffusion induced State-of-Lithiation acceleration time constant,
v is voltage across the resistor capacitor pair, and
R is resistance of the resistor.

12. The method of claim 11, further comprising setting the resistance of the resistor equal to 1 Ohm.

13. The method of claim 11, further comprising simulating various charging events and obtaining output of an average particle State-of-Lithiation and surface particle State-of-Lithiation for the anode and cathode.

14. The method of claim 13, further comprising calibrating the time constant (T) and the acceleration factor (AF) based on the output.

15. A battery monitoring system comprising:
at least one battery module including at least one battery cell, the at least one battery cell including at least a cathode, an anode, and a separator between the anode and the cathode;
a memory configured to store a cathode equivalent circuit model and an anode equivalent circuit model; and
a control module configured to:
modify the cathode equivalent circuit model and the anode equivalent circuit model to define a modified cathode equivalent circuit model and a modified anode equivalent circuit model; and
determine a surface State-of-Lithiation of the cathode and the anode based on the modified cathode equivalent circuit model and the modified anode equivalent circuit model.

16. The battery monitoring system of claim 15, wherein:
the cathode equivalent circuit model is a four parameter (4P) or more equivalent circuit model having one resistor-capacitor pair; and
the anode equivalent circuit model is a four parameter (4P) or more equivalent circuit model having one resistor-capacitor pair.

17. The battery monitoring system of claim 15, wherein the control module is configured to determine a virtual reference electrode value by calculating a potential drop between a load of the at least one battery module and a voltage at a connection node between the separator and the anode.

18. The battery monitoring system of claim 15, wherein the at least one battery module includes multiple battery cells connected in parallel, and a physical reference electrode configured to sense a voltage of at least one of the multiple battery cells.

19. A vehicle comprising:
a drive unit including at least one electric motor configured to rotate wheels of the vehicle;
at least one battery module configured to supply power to the at least one electric motor, the at least one battery module including at least one battery cell, the at least one battery cell including at least a cathode, an anode, and a separator between the anode and the cathode;
a memory configured to store a cathode equivalent circuit model, an anode equivalent circuit model and a separator equivalent circuit model; and
a control module configured to:
modify the cathode equivalent circuit model, the anode equivalent circuit model, and the separator equivalent circuit model to define a modified cathode equivalent circuit model, a modified anode equivalent circuit model, and a modified separator equivalent circuit model; and
estimate a surface State-of-Lithiation of the cathode and a surface State-of-Lithiation of the anode based on the modified cathode equivalent circuit model and the modified anode equivalent circuit model.

20. The vehicle of claim 19, wherein the control module is configured to modify charging current based on the surface State-of-Lithiation of the cathode and the surface State-of-Lithiation of the anode.
